(19) United States
(12) Patent Application Publication
(10) Pub. No.: US 2026/0271550 A1
(43) Pub. Date: Sep. 10, 2026

(54) DISPLAY DEVICE, ELECTRONIC DEVICE INCLUDING THE DISPLAY DEVICE, AND METHOD OF MANUFACTURING THE DISPLAY DEVICE

(71) Applicant: Samsung Display Co., Ltd., Yongin-si (KR)

(72) Inventors: Donggyu Jin, Yongin-si (KR); Yunjong Yeo, Yongin-si (KR); Kyongchol Lee, Yongin-si (KR); Hyunmin Cho, Yongin-si (KR)

(21) Appl. No.: 19/305,219

(22) Filed: Aug. 20, 2025

(30) Foreign Application Priority Data
Mar. 10, 2025 (KR) 10-2025-0030597

(51) Int. Cl. H10K 59/124; H10K 59/12; H10K 59/131

(52) U.S. Cl. CPC H10K 59/124; H10K 59/1201; H10K 59/131

(57) ABSTRACT

A display device includes a substrate; a first inorganic layer disposed on the substrate; a first conductive layer disposed on the first inorganic layer; a second inorganic layer disposed on the first inorganic layer and covering the first conductive layer, where the second inorganic layer defines a first groove portion in an upper portion thereof; a first planarization layer accommodated in the first groove portion; and a second conductive layer disposed on the second inorganic layer and the first planarization layer.

This application claims priority to Korean Patent Application No. 10-2025-0030597, filed on Mar. 10, 2025, and all the benefits accruing therefrom under 35 U.S.C. § 119, the content of which in its entirety is herein incorporated by reference.

### BACKGROUND

### 1. Field

One or more embodiments relate to a device and a method, and more particularly, to a display device, an electronic device including the display device, and a method of manufacturing the display device.

### 2. Description of the Related Art

Mobile electronic devices are widely used. In addition to small electronic devices such as mobile phones, tablet personal computers (PCs) have been widely used in recent years as mobile electronic devices.

Such mobile electronic devices include display devices to support various functions, for example, providing visual information, such as images or videos, to users. Recently, as other parts for driving display devices have been miniaturized, the proportion occupied by display devices in electronic devices has gradually increased. Also, structures that are bendable from a flat state to a certain angle are under development.

### SUMMARY

One or more embodiments include a display device including a sufficiently large area where conductive plates constituting a capacitor are disposed.

However, this is only an example and the scope of the disclosure is not limited thereby.

Additional aspects will be set forth in part in the description which follows and, in part, will be apparent from the description, or may be learned by practice of the presented embodiments of the disclosure.

According to one or more embodiments, a display device includes a substrate, a first inorganic layer disposed on the substrate, a first conductive layer disposed on the first inorganic layer, a second inorganic layer disposed on the first inorganic layer and covering the first conductive layer, where the second inorganic layer defines a first groove portion in an upper portion thereof, a first planarization layer accommodated in the first groove portion, and a second conductive layer disposed on the second inorganic layer and the first planarization layer.

In an embodiment, an end of the second conductive layer may be in contact with the first planarization layer.

In an embodiment, an etch selectivity of the first planarization layer with respect to the second inorganic layer may be greater than 1.

In an embodiment, an upper surface of the first planarization layer may be concave.

In an embodiment, the display device may further include a third inorganic layer disposed on the second inorganic layer and the first planarization layer and covering the second conductive layer, where the third inorganic layer defines in an upper portion thereof a second groove portion overlapping the first groove portion in a plan view, a second planarization layer accommodated in the second groove portion, a third conductive layer disposed on the third inorganic layer and the second planarization layer, and a fourth inorganic layer disposed on the third inorganic layer and the second planarization layer and covering the third conductive layer.

In an embodiment, the first conductive layer, the second conductive layer, and the third conductive layer may overlap each other in the plan view.

In an embodiment, an end of the third conductive layer may be in contact with the second planarization layer.

In an embodiment, the second inorganic layer and the third inorganic layer may include the same material, and the first planarization layer and the second planarization layer may include the same material.

In an embodiment, an upper surface of the second planarization layer may be concave.

According to one or more embodiments, an electronic device includes a substrate, a first inorganic layer disposed on the substrate, a first conductive layer disposed on the first inorganic layer, a second inorganic layer disposed on the first inorganic layer and covering the first conductive layer, where the second inorganic layer defines in an upper portion thereof a first groove portion, a first planarization layer accommodated in the first groove portion, and a second conductive layer disposed on the second inorganic layer and the first planarization layer, wherein an end of the second conductive layer is in contact with the first planarization layer, and an etch selectivity of the first planarization layer with respect to the second inorganic layer is greater than 1.

According to one or more embodiments, a method of manufacturing a display device includes disposing a first inorganic layer on a substrate; disposing a first conductive layer on the first inorganic layer; disposing a second inorganic layer on the first inorganic layer to cover the first conductive layer, where the second inorganic layer defines in an upper portion thereof a first groove portion; disposing a first planarization layer on the second inorganic layer, where the first planarization layer defines in an upper portion thereof a first planarization groove portion overlapping the first groove portion in a plan view; disposing a first sacrificial layer on the first planarization layer such that at least a portion of the first sacrificial layer is accommodated in the first planarization groove portion; removing a portion of the first sacrificial layer to expose an upper surface of the first planarization layer; removing a portion of the first planarization layer and the remainder of the first sacrificial layer such that an upper surface of the second inorganic layer is exposed; and disposing a second conductive layer on the second inorganic layer and the first planarization layer.

In an embodiment, after disposing the first sacrificial layer, an upper surface of the first sacrificial layer may become flat.

In an embodiment, after removing the portion of the first sacrificial layer, an upper surface of the first sacrificial layer and the upper surface of the first planarization layer may become on the same plane.

In an embodiment, after removing the portion of the first planarization layer and the remainder the first sacrificial layer, the upper surface of the first planarization layer may become concave.

In an embodiment, after disposing the second conductive layer, an end of the second conductive layer may become in contact with the first planarization layer.

In an embodiment, an etch selectivity of the first planarization layer with respect to the second inorganic layer may be greater than 1.

In an embodiment, the method may further include disposing a third inorganic layer on the second inorganic layer and the first planarization layer to cover the second conductive layer, where the third inorganic layer defines in an upper portion thereof a second groove portion overlapping the first groove portion in the plan view; disposing a second planarization layer on the third inorganic layer, where the second planarization layer defines in an upper portion thereof a second planarization groove portion overlapping the second groove portion in the plan view; disposing a second sacrificial layer on the second planarization layer such that at least a portion of the second sacrificial layer is accommodated in the second planarization groove portion; removing a portion of the second sacrificial layer to expose an upper surface of the second planarization layer; removing a portion of the second planarization layer and a remainder of the second sacrificial layer such that an upper surface of the third inorganic layer is exposed; and disposing a third conductive layer on the third inorganic layer and the second planarization layer.

In an embodiment, the first conductive layer, the second conductive layer, and the third conductive layer may overlap each other in the plan view.

In an embodiment, the second inorganic layer and the third inorganic layer may include the same material, and the first planarization layer and the second planarization layer may include the same material.

In an embodiment, after removing the portion of the second planarization layer and the remainder of the second sacrificial layer, the upper surface of the second planarization layer may become concave.

Other aspects, features, and advantages of the disclosure will become better understood through the accompanying drawings, the appended claims, and the detailed description.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display device according to an embodiment;

FIG. 2 is a plan view schematically illustrating a display device according to an embodiment;

FIG. 3 is an equivalent circuit diagram illustrating a sub-pixel disposed in a display device, according to an embodiment;

FIGS. 4 and 5 are cross-sectional views schematically illustrating a portion of a display device according to an embodiment;

FIG. 6 is a flowchart schematically showing a method of manufacturing a display device, according to an embodiment;

FIGS. 7 to 16 are cross-sectional views schematically illustrating steps of the method of manufacturing a display device of FIG. 6;

FIG. 17 is a block diagram of an electronic device according to an embodiment; and

FIG. 18 shows schematic diagrams of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

In the following embodiments, the terms “first,” “second,” etc. are not used in a restrictive sense and are used to distinguish one element from another.

The singular forms as used herein are intended to include the plural forms as well unless the context clearly indicates otherwise.

It will be understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly on the other layer, region, or element, but also intervening layers, regions, or elements may be present therebetween.

Also, sizes of elements in the drawings may be exaggerated or reduced for convenience of explanation. For example, because sizes and thicknesses of elements in the drawings are arbitrarily illustrated for convenience of explanation, the disclosure is not necessarily limited thereto.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When a certain embodiment is implemented differently, a specific process sequence may be performed differently from a sequence described herein. For example, two consecutively described processes may be performed substantially at the same time or performed in an order opposite to the stated order.

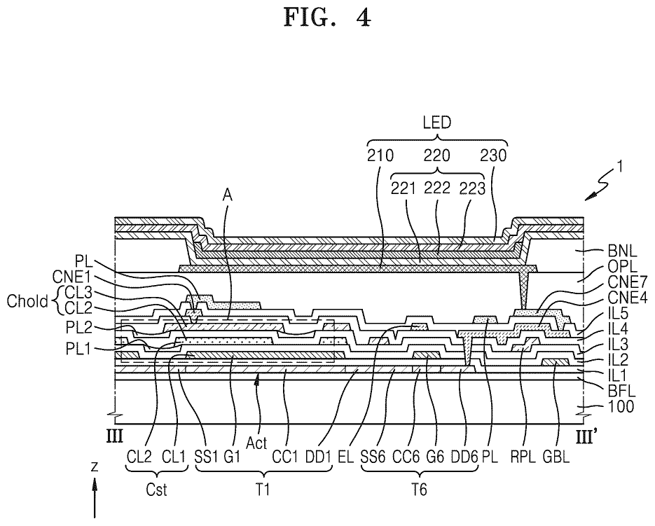

In the present specification, the expression “a plan view” means a view seen from a direction perpendicular to a substrate (see 100 of FIG. 4). For example, the expression “A and B apart from each other in a plan view” means “A and B apart from each other in a view seen from a direction perpendicular to the substrate (see 100 of FIG. 4).”

In the present specification, the expression “a cross-sectional view” means a view obtained by an intersection with a plane in a direction perpendicular to the substrate (see 100 of FIG. 4). For example, the expression “A and B apart from each other in a cross-sectional view” means “A and B apart from each other in a view obtained by an intersection with a plane in a direction perpendicular to the substrate (see 100 of FIG. 4).”

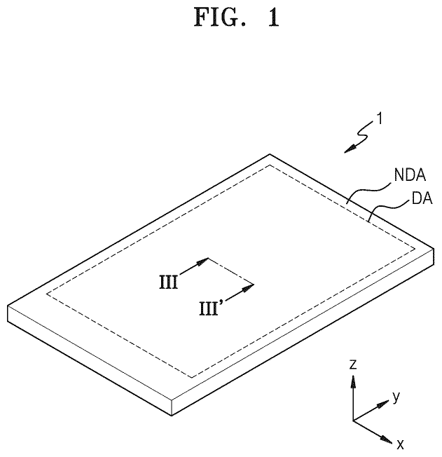

FIG. 1 is a perspective view schematically illustrating a display device 1 according to an embodiment.

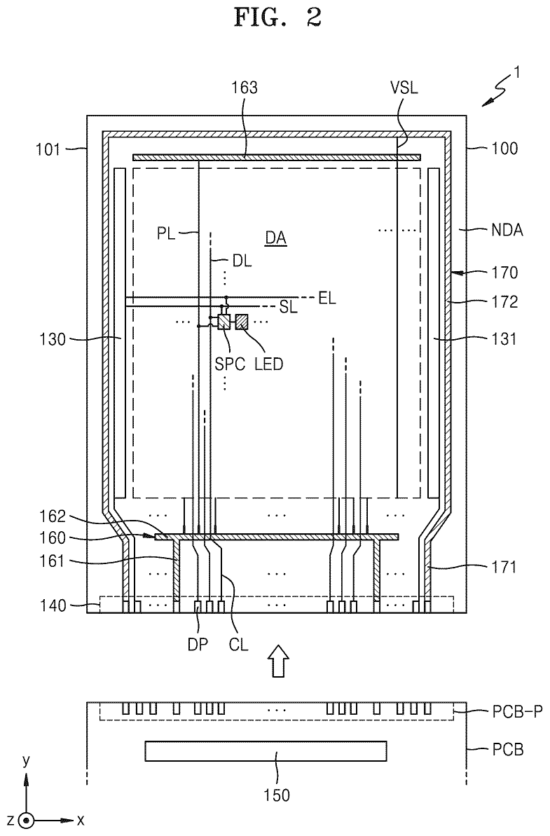

Referring to FIG. 1, the display device 1 may include a display area DA and a non-display area NDA outside the display area DA. Because the display device 1 includes a substrate (see 100 of FIG. 2), it may be understood that the substrate (see 100 of FIG. 2) includes the display area DA and the non-display area NDA. Alternatively, it may be understood that the display area DA and the non-display area NDA are defined in the substrate (see 100 of FIG. 2).

The display area DA may provide a certain image by using light emitted from a plurality of sub-pixels disposed in the display area DA. Each of the sub-pixels may include a display element configured to externally emit light of a certain color. For example, display elements configured to externally emit red light, green light, or blue light may be two-dimensionally disposed along a first direction (e.g., an x-axis direction) and a second direction (e.g., a y-axis direction), and the display area DA in which an image is displayed may be defined. The display area DA may have various shapes, for example, a circular shape, an elliptical shape, a polygonal shape, or a specific figure shape. FIG. 1 illustrates an example in which the display area DA has a substantially rectangular shape. The non-display area NDA may be disposed outside the display area DA. The non-display area NDA may surround at least a portion of the display area DA.

Hereinafter, an organic light-emitting display device is described as an example of the display device 1 according to an embodiment, but the disclosure is not limited thereto. In an embodiment, examples of the display device 1 according to the disclosure may include an inorganic light-emitting display (or an inorganic electroluminescence (EL) display), a quantum dot light-emitting display, and the like. For example, an emission layer of a display element provided in the display device 1 may include an organic material, an inorganic material, or quantum dots, may include an organic material and quantum dots, or may include an inorganic material and quantum dots.

FIG. 2 is a plan view schematically illustrating the display device 1 according to an embodiment.

Referring to FIG. 2, a display panel 101 may include a display area DA and a non-display area NDA. A shape of the display panel 101 may be substantially the same as a shape of the substrate 100. For example, it may be said that the substrate 100 includes the display area DA and the non-display area NDA.

The display area DA may be an area in which an image is displayed. The display area DA may have various shapes, for example, a circular shape, an elliptical shape, a polygonal shape, or a specific figure shape. FIG. 2 illustrates that the display area DA has a substantially rectangular shape, but in another embodiment, the display area DA may have a substantially rectangular shape with round corners.

The display panel 101 may include light-emitting diodes LED disposed in the display area DA and sub-pixel circuits SPC respectively electrically connected to the light-emitting diodes LED. The light-emitting diodes LED and the sub-pixel circuits SPC may be disposed in the first direction (e.g., the x-axis direction) and the second direction (e.g., the y-axis direction) in the display area DA. The sub-pixel circuits SPC may be respectively electrically connected to scan lines SL, emission control lines EL, data lines DL, and driving voltage lines PL, which are disposed in the display area DA.

The scan lines SL and the emission control lines EL may extend in the first direction (e.g., the x-axis direction) and may be respectively electrically connected to the sub-pixel circuits SPC disposed on the same row. The data lines DL and the driving voltage lines PL may extend in the second direction (e.g., the y-axis direction) and may be respectively electrically connected to the sub-pixel circuits SPC disposed on the same column.

The non-display area NDA may be disposed outside the display area DA. The non-display area NDA may completely surround the display area DA.

The display panel 101 may include a first gate driving circuit 130, a second gate driving circuit 131, a first voltage supply line 160, a second voltage supply line 170, and a pad portion 140, which are disposed in the non-display area NDA.

Each of the first gate driving circuit 130 and the second gate driving circuit 131 may include a scan driving circuit and an emission control driving circuit. The scan driving circuit may be configured to provide scan signals to the sub-pixel circuits SPC through the scan lines SL. The emission control driving circuit may be configured to provide emission control signals to the sub-pixel circuits SPC through the emission control lines EL.

The second gate driving circuit 131 may be disposed in parallel with the first gate driving circuit 130 with the display area DA therebetween. Some sub-pixel circuits SPC disposed in the display area DA may be electrically connected to the first gate driving circuit 130, and the remaining sub-pixel circuits SPC may be electrically connected to the second gate driving circuit 131. In another embodiment, the second gate driving circuit 131 may be omitted.

The first voltage supply line 160 and the second voltage supply line 170 may be disposed in the non-display area NDA. The first voltage supply line 160 may include a first sub-line 161 extending in the second direction (e.g., the y-axis direction) toward the end portion of the substrate 100, and a second sub-line 162 and a third sub-line 163 extending in parallel in the first direction (e.g., the x-axis direction) with the display area DA therebetween. The second voltage supply line 170 may partially surround the display area DA in a loop shape with one open side. The second voltage supply line 170 may include a first sub-line 171 extending in the second direction (e.g., the y-axis direction) toward the end portion of the substrate 100, and a second sub-line 172 extending along the edge of the display area DA.

The pad portion 140 may be disposed at one side of the non-display area NDA. The pad portion 140 may include a plurality of pads such as data pads DP. The pad portion 140 may be exposed without being covered by an insulating layer and may be electrically connected to a printed circuit board PCB. The pads of the pad portion 140 may be electrically connected to a terminal portion PCB-P of the printed circuit board PCB. The printed circuit board PCB may be configured to transmit signals or voltages from a controller (not shown) to the display panel 101.

The control signals, which are generated by the controller, may be transmitted to the first gate driving circuit 130 and the second gate driving circuit 131 through the printed circuit board PCB and the pad portion 140.

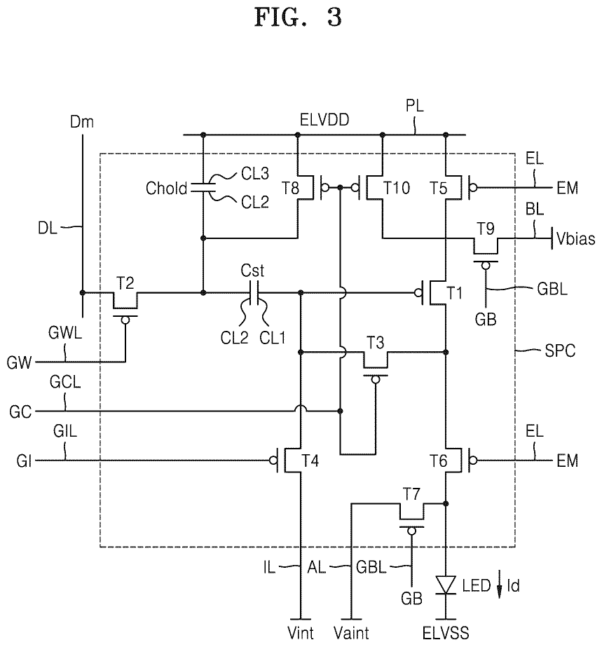

A first driving voltage (see ELVDD of FIG. 3), which is generated by the controller, may be transmitted to the first voltage supply line 160 through the first sub-line 161 connected to the pad of the pad portion 140. The first driving voltage ELVDD may be provided to the sub-pixel circuits SPC through the driving voltage line PL connected to the first voltage supply line 160.

A second driving voltage (see ELVSS of FIG. 3), which is generated by the controller, may be transmitted to the second voltage supply line 170 through the first sub-line 171 connected to the pad of the pad portion 140. The second driving voltage ELVSS may be provided to an opposite electrode (e.g., a cathode) of the light-emitting diode LED connected to the second voltage supply line 170. Common voltage lines VSL electrically connected to the second voltage supply line 170 may be disposed in the display area DA. The common voltage lines VSL may prevent a voltage drop in the second driving voltage ELVSS that may occur as the area of the display area DA increases.

The data driving circuit 150 may be electrically connected to the data lines DL. The data signal (or the data voltage) of the data driving circuit 150 may be provided to the sub-pixel circuits SPC through a connection line CL connected to the data pad DP of the pad portion 140 and the data line DL connected to the connection line CL.

FIG. 2 illustrates that the data driving circuit 150 is disposed on the printed circuit board PCB, but in another embodiment, the data driving circuit 150 may be disposed on the substrate 100. For example, the data driving circuit 150 may be disposed between the pad portion 140 and the first voltage supply line 160.

FIG. 3 is an equivalent circuit diagram illustrating a sub-pixel SPC disposed in a display device, according to an embodiment.

Referring to FIG. 3, the sub-pixel circuit SPC electrically connected to a light-emitting diode LED may include at least one transistor and at least one capacitor. The light-emitting diode LED may include a pixel electrode (e.g., an anode), an opposite electrode (e.g., a cathode), and an intermediate layer disposed between the pixel electrode and the opposite electrode. The intermediate layer may include an emission layer. The pixel electrode of the light-emitting diode LED may be electrically connected to the sub-pixel circuit SPC, and the opposite electrode may be electrically connected to the common voltage line (see VSL of FIG. 2) and/or the second voltage supply line (see 170 of FIG. 2) through which the second driving voltage ELVSS is provided.

As an example, the sub-pixel circuit SPC may include first to tenth transistors T1 to T10, a first capacitor Cst, and a second capacitor Chold.

The sub-pixel circuit SPC may be electrically connected to first to fourth scan lines GWL, GCL, GIL, and GBL configured to respectively transmit first to fourth scan signals GW, GC, GI, and GB, a data line DL configured to transmit a data voltage Dm, an emission control line EL configured to transmit an emission control signal EM, a driving voltage line PL configured to transmit a first driving voltage ELVDD, a first initialization voltage line IL configured to transmit a first initialization voltage Vint, a second initialization voltage line AL configured to transmit a second initialization voltage Vaint, and a bias voltage line BL configured to transmit a bias voltage Vbias.

The first transistor T1 may be a driving transistor in which an amount of a drain current is determined according to a gate-source voltage, and the second to tenth transistors T2 to T10 may each be a switching transistor configured to be turned on/off according to a gate-source voltage and substantially a gate voltage. The first to tenth transistors T1 to T10 may each be provided as a thin-film transistor.

The first capacitor Cst and the second capacitor Chold may be electrically connected to the driving voltage line PL and a gate electrode of the first transistor T1. The first capacitor Cst, which is a storage capacitor, may include a first conductive layer CL1 electrically connected to the gate electrode of the first transistor T1, and a second conductive layer CL2 overlapping the first conductive layer CL1 in a plan view. The second capacitor Chold may include a second conductive layer CL2 and a third conductive layer CL3 connected to the driving voltage line PL. The second conductive layer CL2 of the first capacitor Cst and the second conductive layer CL2 of the second capacitor Chold may be the same as each other.

The first transistor T1 may be configured to control the amount of the driving current Id flowing from the driving voltage line PL to the light-emitting diode LED according to the gate-source voltage. The first transistor T1 may include a gate electrode connected to the first conductive layer CL1 of the first capacitor Cst, a source electrode connected to the driving voltage line PL through the fifth transistor T5, and a drain electrode connected to the light-emitting diode LED through the sixth transistor T6. The second transistor T2 may be configured to electrically connect the data line DL to the second conductive layer CL2 of the first capacitor Cst (or the second conductive layer CL2 of the second capacitor Chold) in response to the first scan signal GW. The second transistor T2 may be configured to transmit the data voltage Dm to the second conductive layer CL2 of the first capacitor Cst (or the second conductive layer CL2 of the second capacitor Chold) in response to the first scan signal GW.

The third transistor T3 may be configured to electrically connect the drain electrode and the gate electrode of the first transistor T1 to each other in response to the second scan signal GC. The third transistor T3 may be connected in series between the drain electrode and the gate electrode of the first transistor T1.

The fourth transistor T4 may be configured to electrically connect the first initialization voltage line IL to the gate electrode of the first transistor T1 in response to the third scan signal GI. The fourth transistor T4 may be configured to apply the first initialization voltage Vint to the gate electrode of the first transistor T1 in response to the third scan signal GI.

The fifth transistor T5 may be configured to electrically connect the driving voltage line PL to the source electrode of the first transistor T1 in response to the emission control signal EM. The fifth transistor T5 may be configured to apply the first driving voltage ELVDD to the source electrode of the first transistor T1 in response to the emission control signal EM.

The sixth transistor T6 may be configured to connect the drain electrode of the first transistor T1 to the pixel electrode (e.g., the anode) of the light-emitting diode LED in response to the emission control signal EM. The sixth transistor T6 may be configured to electrically connect the drain electrode of the first transistor T1 to the pixel electrode (e.g., the anode) of the light-emitting diode LED in response to the emission control signal EM.

FIG. 3 illustrates that the fifth transistor T5 and the sixth transistor T6 operate in response to the same emission control signal EM, but in another embodiment, the fifth transistor T5 and the sixth transistor T6 may operate in response to different emission control signals. For example, the fifth transistor T5 may have a gate electrode connected to a first emission control line and may be configured to electrically connect the driving voltage line PL to the source electrode of the first transistor T1 in response to a first emission control signal. The sixth transistor T6 may have a gate electrode connected to a second emission control line and may be configured to electrically connect the drain electrode of the first transistor T1 to the pixel electrode (e.g., the anode) of the light-emitting diode LED in response to a second emission control signal.

The seventh transistor T7 may be configured to electrically connect the second initialization voltage line AL to the pixel electrode (e.g., the anode) of the light-emitting diode LED in response to the fourth scan signal GB. The seventh transistor T7 may be configured to apply the second initialization voltage Vaint to the pixel electrode (e.g., the anode) of the light-emitting diode LED in response to the fourth scan signal GB.

The eighth transistor T8 may be configured to electrically connect the driving voltage line PL to the second conductive layer CL2 of the first capacitor Cst or the second conductive layer CL2 of the second capacitor Chold in response to the first scan signal GW. The eighth transistor T8 may be configured to apply the first driving voltage ELVDD to the second conductive layer CL2 of the first capacitor Cst or the second conductive layer CL2 of the second capacitor Chold in response to the second scan signal GC.

The ninth transistor T9 may be configured to connect the bias voltage line BL to the source electrode of the first transistor T1 in response to the fourth scan signal GB. The ninth transistor T9 may be configured to apply the bias voltage Vbias to the source electrode of the first transistor T1 in response to the fourth scan signal GB.

The tenth transistor T10 may be configured to electrically connect the driving voltage line PL to the drain electrode of the fifth transistor T5 in response to the second scan signal GC.

FIG. 3 illustrates that the seventh transistor T7 and the ninth transistor T9 operate in response to the same fourth scan signal GB, but in another embodiment, the seventh transistor T7 and the ninth transistor T9 may operate in response to different scan signals.

The second scan signal GC may be substantially synchronized with the first scan signal GW. The third scan signal GI may be substantially synchronized with the first scan signal GW of the previous row. The fourth scan signal GB may be substantially synchronized with the first scan signal GW. In another embodiment, the fourth scan signal GB may be substantially synchronized with the first scan signal GW of the next row or the third scan signal GI of the next row.

In an embodiment, the first to tenth transistors T1 to T10 may each include a semiconductor layer including silicon. For example, the first to tenth transistors T1 to T10 may each include a semiconductor layer including low temperature polysilicon (LTPS). Polysilicon may have high electron mobility (100 cm²/Vs or more), low energy consumption, and excellent reliability.

In another embodiment, the first to tenth transistors T1 and T10 may each include an oxide of at least one selected from indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the semiconductor layer may be an InSnZnO (ITZO) semiconductor layer, an InGaZnO (IGZO) semiconductor layer, or the like.

In another embodiment, some semiconductor layers of the first to tenth transistors T1 to T10 may each include LTPS, and other semiconductor layers of the first to tenth transistors T1 to T10 may each include an oxide semiconductor (e.g., IGZO, etc.).

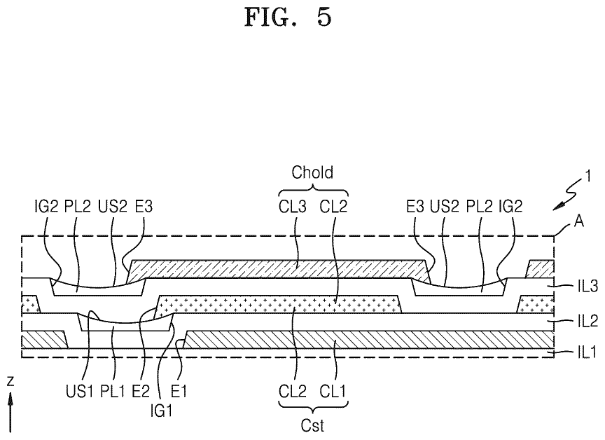

FIGS. 4 and 5 are cross-sectional views schematically illustrating a portion of a display device 1 according to an embodiment.

Specifically, FIG. 4 is a cross-sectional view of the display device 1 taken along line III-III′ of FIG. 1, and FIG. 5 is an enlarged view of region A of the display device 1 illustrated in FIG. 4.

Referring to FIGS. 3 to 5, the display device 1 may include a substrate 100, one or more transistors, one or more capacitors, a plurality of inorganic layers, a plurality of organic layers, and a light-emitting diode LED.

The substrate 100 may include various materials, such as glass, metal, or plastic. According to an embodiment, the substrate 100 may include a flexible material. The flexible material refers to a bendable, foldable, or rollable material. The substrate 100 including the flexible material may include ultra-thin glass, metal, or plastic.

A buffer layer BFL may be disposed on the substrate 100. The buffer layer BFL may be a single layer or layers including an inorganic insulating material, such as silicon nitride, silicon oxide, and/or silicon oxynitride.

A semiconductor layer Act may be disposed on the buffer layer BFL. The semiconductor layer Act is a layer including a plurality of curved portions, and the first to tenth transistors T1 to T10 may be formed along the curved portions of the semiconductor layer Act. A first inorganic layer IL1 may be disposed on the buffer layer BFL and cover the semiconductor layer Act. That is, the first inorganic layer IL1 may be disposed on the substrate 100.

Conductive patterns may be disposed on the first inorganic layer IL1. For example, a first gate electrode G1 of the first transistor T1 may be disposed on a first inorganic layer IL1. The first gate electrode G1 may be a portion overlapping a channel region CC1 of a first semiconductor in a plan view, which is a portion of the semiconductor layer Act. The first semiconductor may include a source region SS1 and a drain region DD1 respectively on both sides of the channel region CC1. The first gate electrode G1 and the first semiconductor, which is a portion of the semiconductor layer Act, may constitute the first transistor T1. The first gate electrode G1 may be the first conductive layer CL1 of the first capacitor Cst. In other words, a portion of the first conductive layer CL1 of the first capacitor Cst may be the first gate electrode G1 of the first transistor T1. In such a structure, the first conductive layer CL1 may be disposed on the first inorganic layer IL1.

For example, a sixth gate electrode G6 of the sixth transistor T6 may be disposed on the first inorganic layer IL1. The sixth gate electrode G6 may be a portion overlapping a channel region CC6 of a sixth semiconductor in a plan view, which is a portion of the semiconductor layer Act. The sixth semiconductor may include a source region SS6 and a drain region DD6 respectively on both sides of the channel region CC6. The sixth gate electrode G6 and the sixth semiconductor, which is a portion of the semiconductor layer Act, may constitute the sixth transistor T6.

For example, a fourth scan line GBL may be disposed on the first inorganic layer IL1. The fourth scan line GBL may be apart from the semiconductor layer Act. The fourth scan line GBL may be configured to receive the fourth scan signal GB from the scan driving circuit.

The first gate electrode G1 (the first conductive layer CL1), the sixth gate electrode G6, and the fourth scan line GBL may be disposed on the same layer and may include the same material. The first gate electrode G1 (the first conductive layer CL1), the sixth gate electrode G6, and the fourth scan line GBL may each include a conductive material including molybdenum (Mo), aluminum (Al), copper (Cu), titanium (Ti), or the like. The first gate electrode G1 (the first conductive layer CL1), the sixth gate electrode G6, and the fourth scan line GBL may each include a single layer or layers including the conductive material described above. For example, the first gate electrode G1 (the first conductive layer CL1), the sixth gate electrode G6, and the fourth scan line GBL may each have a single layer structure of molybdenum.

A second inorganic layer IL2 may be disposed on the first inorganic layer IL1 and cover the first gate electrode G1, the sixth gate electrode G6, and the fourth scan line GBL. That is, the second inorganic layer IL2 may cover the first conductive layer CL1. The second inorganic layer IL2 may be in contact with an end E1 of the first conductive layer CL1. The second inorganic layer IL2 may define in an upper portion thereof a first groove portion IG1. Because a curvature is formed in the second inorganic layer IL2 due to the disposition of the first conductive layer CL1 protruding in the third direction (e.g., the z-axis direction), the first groove portion IG1 may be formed at a grooved position of the second inorganic layer IL2. The first groove portion IG1 may accommodate a first planarization layer PL1. An upper surface US1 of the first planarization layer PL1 may be concave. Because the first planarization layer PL1 is disposed in the first groove portion IG1, the curvature formed in the second inorganic layer IL2 may be alleviated. The first planarization layer PL1 may be in contact with the side surface of the second inorganic layer IL2 where the first groove portion IG1 is formed. In an embodiment, the height of the upper surface US1 at the point in contact with the side surface of the second inorganic layer IL2 may be the same as the height of an upper surface of the second inorganic layer IL2 outside the first groove portion IG1 such that there is no step difference at the point.

Conductive patterns may be disposed on the second inorganic layer IL2 and the first planarization layer PL1. For example, the second conductive layer CL2 may be disposed on the second inorganic layer IL2 and the first planarization layer PL1. The second conductive layer CL2 may be disposed to overlap the first conductive layer CL1. The first conductive layer CL1 and the second conductive layer CL2, which overlap each other in a plan view, may constitute the first capacitor Cst. An end E2 of the second conductive layer CL2 may be in contact with the first planarization layer PL1. In an embodiment, a lower surface of the second conductive layer CL2 overlapping the first groove portion IG1 may be in contact with the upper surface US1 of the first planarization layer PL1. Because the first planarization layer PL1 filled in the first groove portion IG1 alleviates the step formed between the first groove portion IG1 and an upper surface of the second inorganic layer IL2 outside the first groove portion IG1, the step coverage of the layer (e.g., the second inorganic layer IL2 and the first planarization layer PL1) supporting the second conductive layer CL2 may be improved. Because the layer supporting the second conductive layer CL2 is planarized, the area of the second conductive layer CL2 may increase. Therefore, the capacitance of the first capacitor Cst may be improved (e.g., increase).

The third inorganic layer IL3 may be disposed on the second inorganic layer IL2 and the first planarization layer PL1 and cover the second conductive layer CL2. The third inorganic layer IL3 may be in contact with the end E2 of the second conductive layer CL2. The third inorganic layer IL3 may define in an upper portion thereof a second groove portion IG2. The second groove portion IG2 may overlap the first groove portion IG1 in a plan view. Because a curvature is formed in the third inorganic layer IL3 due to the disposition of the second conductive layer CL2 protruding in the third direction (e.g., the z-axis direction), the second groove portion IG2 may be formed at a grooved position of the third inorganic layer IL3. The second groove portion IG2 may accommodate a second planarization layer PL2. An upper surface US2 of the second planarization layer PL2 may be concave. Because the second planarization layer PL2 is disposed in the second groove portion IG2, the curvature formed in the third inorganic layer IL3 may be alleviated. The second planarization layer PL2 may be in contact with the side surface of the third inorganic layer IL3 where the second groove portion IG2 is formed. In an embodiment, the height of the upper surface US2 at the point in contact with the side surface of the third inorganic layer IL3 may be the same as the height of an upper surface of the third inorganic layer IL3 outside the second groove portion IG2 such that there is no step difference at the point.

Conductive patterns may be disposed on the third inorganic layer IL3 and the second planarization layer PL2. For example, the third conductive layer CL3 may be disposed on the third inorganic layer IL3 and the second planarization layer PL2. The third conductive layer CL3 may be disposed to overlap the second conductive layer CL2. The first conductive layer CL1, the second conductive layer CL2, and the third conductive layer CL3 may overlap each other. The second conductive layer CL2 and the third conductive layer CL3, which overlap each other in a plan view, may constitute the second capacitor Chold. An end E3 of the third conductive layer CL3 may be in contact with the second planarization layer PL2. In an embodiment, a lower surface of the third conductive layer CL3 overlapping the second groove portion IG2 may be in contact with the upper surface US2 of the second planarization layer PL2. Because the second planarization layer PL2 filled in the second groove portion IG2 alleviates the step formed between the second groove portion IG2 and an upper surface of the third inorganic layer IL3 outside the second groove portion IG2, the step coverage of the layer (the second planarization layer PL2 and the third inorganic layer IL3) supporting the third conductive layer CL3 may be improved. Because the layer supporting the third conductive layer CL3 is planarized, the area of the third conductive layer CL3 may increase. Therefore, the capacitance of the second capacitor Chold may be improved (e.g., increase). For example, a repair line RPL may be disposed on the third inorganic layer IL3. The repair line RPL may be apart from the third conductive layer CL3.

The third conductive layer CL3 and the repair line RPL may be disposed on the same layer and may include the same material. The third conductive layer CL3 and the repair line RPL may each include a conductive material including molybdenum (Mo), aluminum (Al), copper (Cu), titanium (Ti), or the like. The third conductive layer CL3 and the repair line RPL may each include a layer or layers including the conductive material described above. For example, the third conductive layer CL3 and the repair line RPL may each have a single layer structure of molybdenum.

A fourth inorganic layer IL4 may be disposed on the third inorganic layer IL3 and the second planarization layer PL2 and cover the third conductive layer CL3 and the repair line RPL. The fourth inorganic layer IL4 may be in contact with the end E3 of the third conductive layer CL3. Conductive patterns may be disposed on the fourth inorganic layer IL4. For example, a first connection electrode CNE1, a fourth connection electrode CNE4, and an emission control line may be disposed on the fourth inorganic layer IL4. The first connection electrode CNE1, the fourth connection electrode CNE4, and the emission control line may be disposed on the same layer and may include the same material. The first connection electrode CNE1, the fourth connection electrode CNE4, and the emission control line may each include a conductive material including molybdenum (Mo), aluminum (Al), copper (Cu), titanium (Ti), or the like. The first connection electrode CNE1, the fourth connection electrode CNE4, and the emission control line may include a layer or layers including the conductive material described above. For example, the first connection electrode CNE1, the fourth connection electrode CNE4, and the emission control line may each have a single layer structure of molybdenum.

The first connection electrode CNE1 may be electrically connected to the third conductive layer CL3 through a contact hole formed in the fourth inorganic layer IL4. The fourth connection electrode CNE4 may be electrically connected to the drain region of the sixth semiconductor of the sixth transistor T6 through contact holes formed in the first inorganic layer IL1, the second inorganic layer IL2, the third inorganic layer IL3, and the fourth inorganic layer IL4. The emission control line EL may be configured to receive the emission control signal EM from the emission control driving circuit.

A fifth inorganic layer IL5 may be disposed on the fourth inorganic layer IL4 and cover the first connection electrode CNE1, the fourth connection electrode CNE4, and the emission control line. Conductive patterns may be disposed on the fifth inorganic layer IL5. For example, a driving voltage line PL and a seventh connection electrode CNE7 may be disposed on the fifth inorganic layer IL5. The driving voltage line PL may be configured to receive a first power supply voltage ELVDD from the first voltage supply line 160. The driving voltage line PL may be electrically connected to the first connection electrode CNE1 through a contact hole formed in the fifth inorganic layer IL5. The seventh connection electrode CNE7 may be electrically connected to the fourth connection electrode CNE4 through a contact hole formed in the fifth inorganic layer IL5.

The driving voltage line PL and the seventh connection electrode CNE7 may be disposed on the same layer and include the same material. The driving voltage line PL and the seventh connection electrode CNE7 may each include a conductive material including molybdenum (Mo), aluminum (Al), copper (Cu), titanium (Ti), or the like. The driving voltage line PL and the seventh connection electrode CNE7 may each include a layer or layers including the conductive material described above. For example, the driving voltage line PL and the seventh connection electrode CNE7 may each have a single layer structure of molybdenum.

The first inorganic layer IL1, the second inorganic layer IL2, the third inorganic layer IL3, the fourth inorganic layer IL4, and the fifth inorganic layer IL5 may include the same material. For example, the first inorganic layer IL1, the second inorganic layer IL2, the third inorganic layer IL3, the fourth inorganic layer IL4, and the fifth inorganic layer IL5 may each include an inorganic insulating material, such as silicon oxide, silicon nitride, silicon oxynitride, aluminum oxide, titanium oxide, tantalum oxide, or hafnium oxide. However, this is an example, and the materials of the first inorganic layer IL1, the second inorganic layer IL2, the third inorganic layer IL3, the fourth inorganic layer IL4, and the fifth inorganic layer IL5 are not limited thereto.

The first planarization layer PL1 and the second planarization layer PL2 may include the same material. The first planarization layer PL1 and the second planarization layer PL2 may each include aluminum oxide (AlOₓ), titanium oxide (TiOₓ), silicon oxide (SiOₓ), aluminum nitride (AlNₓ, AlON), titanium nitride (TiNₓ, TiONₓ), silicon nitride (SiNₓ, SiONₓ), Al, Ti, Mo, Ag, Cu, Fe, Cr, NI, Zn, Sn, or the like.

The etching selectivity of each of the first planarization layer PL1 and the second planarization layer PL2 with respect to each of the first inorganic layer IL1, the second inorganic layer IL2, the third inorganic layer IL3, the fourth inorganic layer IL4, and the fifth inorganic layer IL5 may be greater than 1. Specifically, the etch selectivity of the first planarization layer PL1 with respect to the second inorganic layer IL2 may be greater than 1. The etch selectivity of the second planarization layer PL2 with respect to the fourth inorganic layer IL4 may be greater than 1.

An organic planarization layer OPL may be disposed on the fifth inorganic layer IL5 and cover the driving voltage line PL and the seventh connection electrode CNE7. The organic planarization layer OPL may planarize a curved surface by the plurality of inorganic layers disposed therebelow. The organic planarization layer OPL may include general-purpose polymer (e.g., benzocyclobutene (BCB), polyimide, hexamethyldisiloxane (HMDSO), polymethylmethacrylate (PMMA), or polystyrene (PS)), polymer derivatives having a phenolic group, acrylic-based polymer, imide-based polymer, aryl ether-based polymer, amide-based polymer, fluorine-based polymer, p-xylene-based polymer, vinyl alcohol-based polymer, or any blend thereof.

A pixel electrode 210 may be disposed on the organic planarization layer OPL. In some embodiments, the pixel electrode 210 may include a reflective layer and a transparent or semitransparent electrode layer disposed on the reflective layer. The reflective layer may include Ag, Mg, Al, Pt, Pd, Au, Ni, Nd, Ir, Cr, or any compound thereof. The transparent or semitransparent electrode layer may include at least one selected from indium tin oxide (ITO), indium zinc oxide (IZO), zinc oxide (ZnO), indium oxide (In₂O₃), indium gallium oxide (IGO), and aluminum zinc oxide (AZO). In some embodiments, the pixel electrode 210 may have a stack structure of ITO/Ag/ITO.

The pixel electrode 210 may be electrically connected to the seventh connection electrode CNE7 through a contact hole formed in the lower insulating layer. Accordingly, the pixel electrode 210 may be electrically connected to the drain region DD6 of the sixth transistor T6 through the seventh connection electrode CNE7 and the fourth connection electrode CNE4.

A bank layer BNL may be disposed on the organic planarization layer OPL. The bank layer BNL may have a pixel opening exposing at least a portion of the pixel electrode 210. The bank layer BNL may include at least one organic insulating material selected from polyimide, polyamide, acrylic resin, BCB, and phenol resin. Alternatively, the bank layer BNL may include an inorganic insulating material, such as silicon nitride, silicon oxide, and/or silicon oxynitride.

At least a portion of an intermediate layer 220 may be disposed within the pixel opening of the bank layer BNL. The intermediate layer 220 may include a first functional layer 221 disposed below an emission layer 222 and/or a second functional layer 223 disposed above the emission layer 222. The first functional layer 221 may include a hole transport layer (HTL) and/or a hole injection layer (HIL). The emission layer 222 may include a high molecular weight organic material or a low molecular weight organic material that emits light of a certain color. The second functional layer 223 may include an electron transport layer (ETL) and/or an electron injection layer (EIL). The first functional layer 221 and the second functional layer 223 may each include an organic material.

An opposite electrode 230 may be a transmissive electrode or a reflective electrode. In some embodiments, the opposite electrode 230 may be a transparent or semitransparent electrode, and may include a metal thin-film having a low work function and including Li, Ca, LiF/Ca, LiF/Al, Al, Ag, Mg, and/or any compound thereof. In addition, a transparent conductive oxide (TCO) layer, such as ITO, IZO, ZnO, or In₂O₃, may be further disposed on the metal thin-film. The pixel electrode 210, the intermediate layer 220, and the opposite electrode 230 may constitute a light-emitting diode LED.

The light-emitting diode LED may be covered with an encapsulation layer including at least one organic encapsulation layer and at least one inorganic encapsulation layer. Although the structure and disposition relationship of the sub-pixel circuit SPC and the lines have been described above with reference to FIG. 4, this is only an example and the disclosure is not limited thereto and may be variously modified.

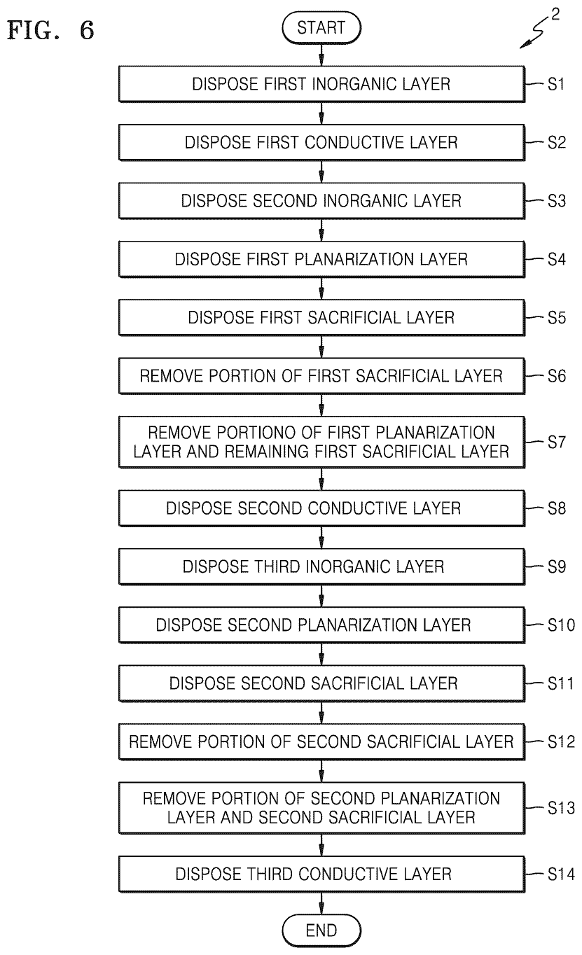

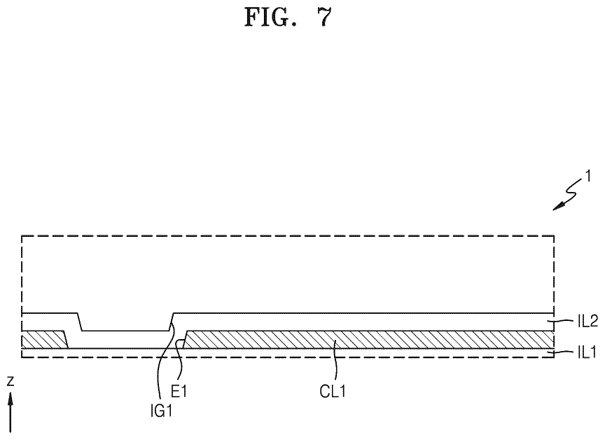

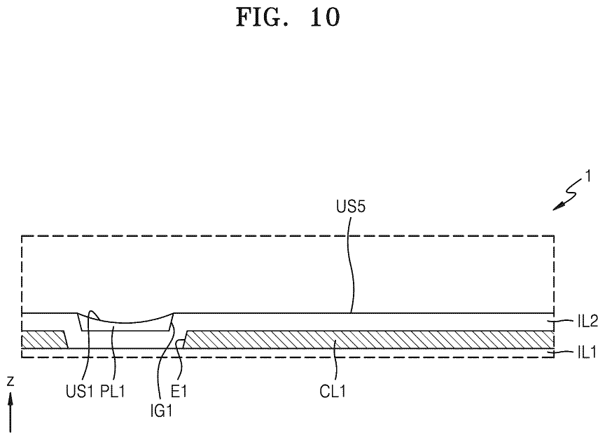

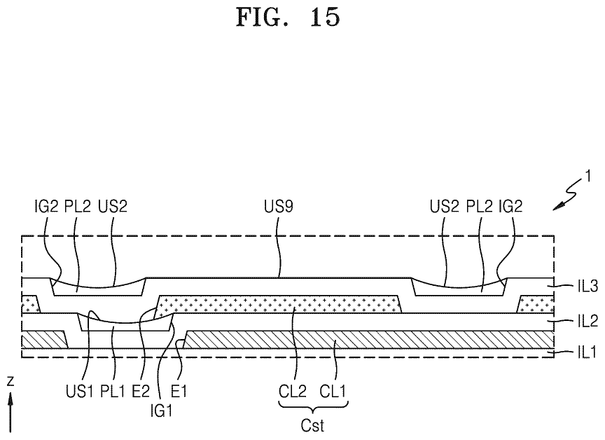

FIG. 6 is a flowchart schematically showing a method 2 of manufacturing a display device, according to an embodiment, and FIGS. 7 to 16 are cross-sectional views schematically illustrating steps of the method of manufacturing a display device of FIG. 6.

Specifically, FIGS. 7 to 16 are enlarged views of region A of the display device 1 illustrated in FIG. 4.

In FIGS. 7 to 16, the same reference numerals as those in FIGS. 4 and 5 denote the same members, and a redundant description thereof is omitted.

A method 2 of manufacturing a display device 1 is described with reference to FIGS. 6 to 16.

Referring to FIGS. 6 and 7, the method 2 of manufacturing a display device may include disposing a first inorganic layer IL1 on a substrate (see 100 of FIG. 4) (S1), disposing a first conductive layer CL1 on the first inorganic layer IL1 (S2), and disposing a second inorganic layer IL2 on the first inorganic layer IL1 to cover the first conductive layer CL1 (S3).

In the disposing of the second inorganic layer IL2 (S3), the second inorganic layer IL2 may define in an upper portion thereof a first groove portion IG1. Because the first conductive layer CL1 protrudes from the first inorganic layer IL1 in the third direction (e.g., in the z-axis direction), the first groove portion IG1 may be formed in the second inorganic layer IL2 along an end E1 of the first conductive layer CL1.

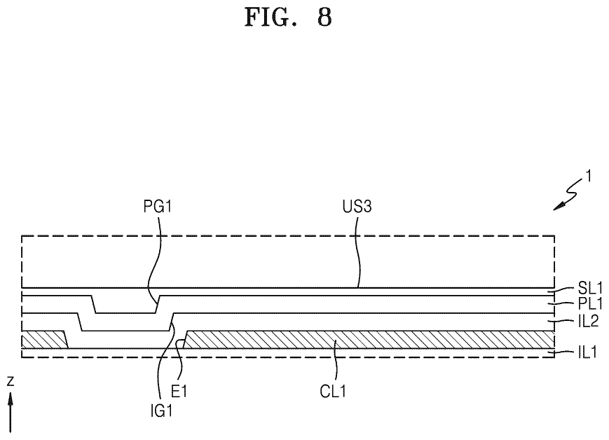

Referring to FIGS. 6 and 8, the method 2 of manufacturing a display device may include disposing a first planarization layer PL1 on the second inorganic layer IL2 (S4), and disposing a first sacrificial layer SL1 on the first planarization layer PL1 (S5).

In the disposing of the first planarization layer PL1 (S4), the first planarization layer PL1 may define in an upper portion thereof a first planarization groove portion PG1. Because the second inorganic layer IL2 defines in an upper portion thereof the first groove portion IG1, the first planarization groove portion PG1 may be formed in the first planarization layer PL1 along the first groove portion IG1. The first planarization groove portion PG1 may overlap the first groove portion IG1 in a plan view.

In the disposing of the first sacrificial layer SL1 (S5), at least a portion of the first sacrificial layer SL1 may be accommodated in the first planarization groove portion PG1. The first sacrificial layer SL1 may cover the first planarization layer PL1 and may planarize the first planarization groove portion PG1. An upper surface US3 of the first sacrificial layer SL1 may be flat. In other words, the height of a portion of the upper surface US3 overlapping the first planarization groove portion PG1 may be the same as the height of another portion of the upper surface US3 not overlapping the first planarization groove portion PG1 in a plan view. The first sacrificial layer SL1 may include a photoresist material or an organic layer material. For example, the first sacrificial layer SL1 may include acrylic, polyimide, PMMA, novolac resin, epoxy, carbonol, or a photosensitive polymer material.

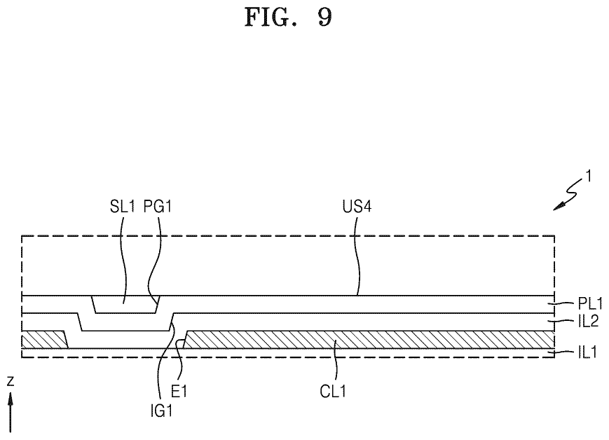

Referring to FIGS. 6 and 9, the method 2 of manufacturing a display device may include removing a portion of the first sacrificial layer SL1 so that an upper surface US4 of the first planarization layer PL1 is exposed (S6).

In the removing of a portion of the first sacrificial layer SL1 (S6), an upper portion of the first sacrificial layer SL1 may be removed until the upper surface US4 of the first planarization layer PL1 is exposed. A portion of the first sacrificial layer SL1 accommodated in the first planarization groove portion PG1 may not be removed. The upper surface US3 of the first sacrificial layer SL1 and the upper surface US4 of the first planarization layer PL1 may have the same plane.

A portion of the first sacrificial layer SL1 may be removed by a dry ashing process. The dry ashing process may be performed by using plasma including oxygen (O₂), ozone (O₃), hydrogen (H₂), fluorine (F), or any combination thereof. In general, a portion of the first sacrificial layer SL1 may be removed by using oxygen (O₂) plasma, and may be optimized by adjusting radio frequency (RF) power, process pressure, temperature, and gas composition ratio when necessary.

Referring to FIGS. 6, 9, and 10, the method 2 of manufacturing a display device may include removing a portion of the first planarization layer PL1 and the remainder of the first sacrificial layer SL1 (S7).

The etch selectivity of the first sacrificial layer SL1 with respect to the first planarization layer PL1 may be substantially 1. Therefore, the first planarization layer PL1 and the first sacrificial layer SL1 may be removed at substantially the same rate. In the removing of a portion of the first planarization layer PL1 and the remainder of the first sacrificial layer SL1 (S7), the first sacrificial layer SL1 may be removed until an upper surface US5 of the second inorganic layer IL2 is exposed. Because the etch selectivity of the first planarization layer PL1 with respect to the second inorganic layer IL2 is greater than 1, the upper surface US1 of the first planarization layer PL1 may be concave.

Because the first planarization layer PL1 is accommodated in the first groove portion IG1, a phenomenon in which a lower surface of the second conductive layer CL2 is exposed from the second inorganic layer IL2 due to excessive etching of the second inorganic layer IL2 forming the first groove portion IG1 may be effectively reduced. In addition, a phenomenon in which an undercut structure is formed in the second inorganic layer IL2 forming the first groove portion IG1 may be effectively reduced.

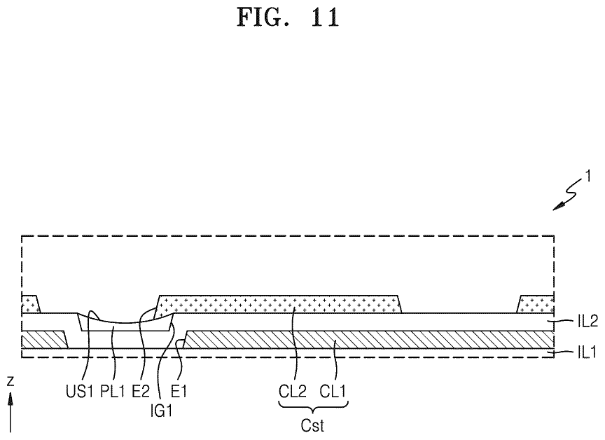

Referring to FIGS. 6 and 11, the method 2 of manufacturing a display device may include disposing a second conductive layer CL2 on the second inorganic layer IL2 and the first planarization layer PL1 (S8).

In the disposing of the second conductive layer CL2 (S8), the second conductive layer CL2 may be disposed to overlap the first conductive layer CL1 in a plan view. In addition, an end E2 of the second conductive layer CL2 may be in contact with the first planarization layer PL1. The first conductive layer CL1 and the second conductive layer CL2, which overlap each other, may be disposed with the second inorganic layer IL2 therebetween. The first conductive layer CL1 and the second conductive layer CL2 may constitute a first capacitor Cst, and the second inorganic layer IL2 may act as a dielectric layer.

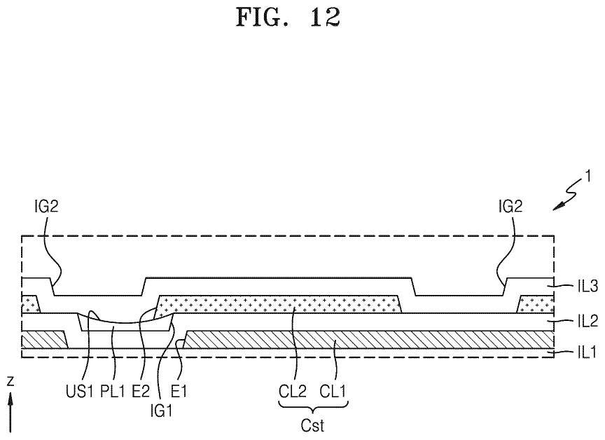

Referring to FIGS. 6 and 12, the method 2 of manufacturing a display device may include disposing a third inorganic layer IL3 on the second inorganic layer IL2 and the first planarization layer PL1 to cover the second conductive layer CL2 (S9).

In the disposing of the third inorganic layer IL3 (S9), the third inorganic layer IL3 may define in an upper portion thereof a second groove portion IG2. Because the second conductive layer CL2 protrudes from the second inorganic layer IL2 in the third direction (e.g., in the z-axis direction), the second groove portion IG2 may be formed in the third inorganic layer IL3 along the end E2 of the second conductive layer CL2. The second groove portion IG2 may overlap the first groove portion IG1 in a plan view.

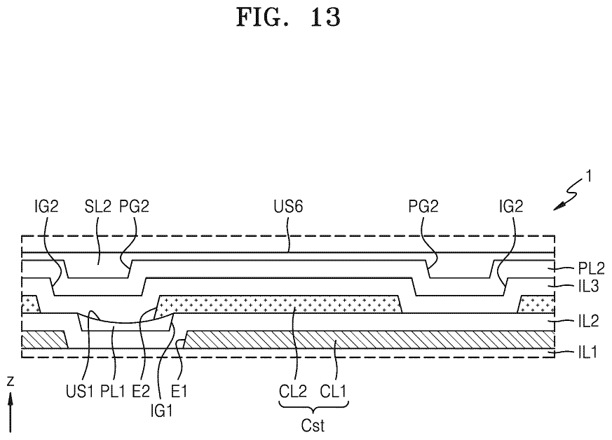

Referring to FIGS. 6 and 13, the method 2 of manufacturing a display device may include disposing a second planarization layer PL2 on the third inorganic layer IL3 (S10), and disposing a second sacrificial layer SL2 on the second planarization layer PL2 (S11).

In the disposing of the second planarization layer PL2 (S10), the second planarization layer PL2 may define in an upper portion thereof a second planarization groove portion PG2. Because the third inorganic layer IL3 defines in an upper portion thereof the second groove portion IG2, the second planarization groove portion PG2 may be formed in the second planarization layer PL2 along the second groove portion IG2. The second planarization groove portion PG2 may overlap the second groove portion IG2 in a plan view.

In the disposing of the second sacrificial layer SL2 (S11), at least a portion of the second sacrificial layer SL2 may be accommodated in the second planarization groove portion PG2. The second sacrificial layer SL2 may cover the second planarization layer PL2 and may planarize the second planarization groove portion PG2. An upper surface US6 of the second sacrificial layer SL2 may be flat. In other words, the height of a portion of the upper surface US6 overlapping the second planarization groove portion PG2 may be the same as the height of another portion of the upper surface US6 not overlapping the second planarization groove portion PG2 in a plan view. The second sacrificial layer SL2 may include a photoresist material or an organic layer material. For example, the second sacrificial layer SL2 may include the same material as the first sacrificial layer SL1.

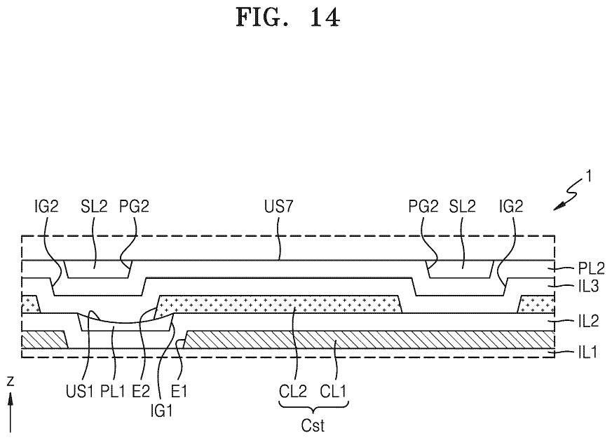

Referring to FIGS. 6 and 14, the method 2 of manufacturing a display device may include removing a portion of the second sacrificial layer SL2 so that an upper surface US7 of the second planarization layer PL2 is exposed (S12).

In the removing of a portion of the second sacrificial layer SL2 (S12), an upper portion of the second sacrificial layer SL2 may be removed until the upper surface US7 of the second planarization layer PL2 is exposed. A portion of the second sacrificial layer SL2 accommodated in the second planarization groove portion PG2 may not be removed. The upper surface US6 of the second sacrificial layer SL2 and the upper surface US7 of the second planarization layer PL2 may have the same plane.

A portion of the second sacrificial layer SL2 may be removed by a dry ashing process. The dry ashing process may be performed by using plasma including oxygen (O₂), ozone (O₃), hydrogen (H₂), fluorine (F), or any combination thereof. In general, a portion of the second sacrificial layer SL2 may be removed by using oxygen (O₂) plasma, and may be optimized by adjusting radio frequency (RF) power, process pressure, temperature, and gas composition ratio when necessary.

Referring to FIGS. 6, 14, and 15, the method 2 of manufacturing a display device may include removing a portion of the second planarization layer PL2 and the remainder of the second sacrificial layer SL2 (S13).

The etch selectivity of the second sacrificial layer SL2 with respect to the second planarization layer PL2 may be substantially 1. Therefore, the second planarization layer PL2 and the second sacrificial layer SL2 may be removed at substantially the same rate. In the removing of a portion of the second planarization layer PL2 and the remainder of the second sacrificial layer SL2 (S13), the second sacrificial layer SL2 may be removed until an upper surface US8 of the third inorganic layer IL3 is exposed. Because the etch selectivity of the second planarization layer PL2 with respect to the third inorganic layer IL3 is greater than 1, the upper surface US7 of the second planarization layer PL2 may be concave.

Because the second planarization layer PL2 is accommodated in the second groove portion IG2, a phenomenon in which a lower surface of the third conductive layer CL3 is exposed from the third inorganic layer IL3 due to excessive etching of the third inorganic layer IL3 forming the second groove portion IG2 may be effectively reduced. In addition, a phenomenon in which an undercut structure is formed in the third inorganic layer IL3 forming the second groove portion IG2 may be effectively reduced.

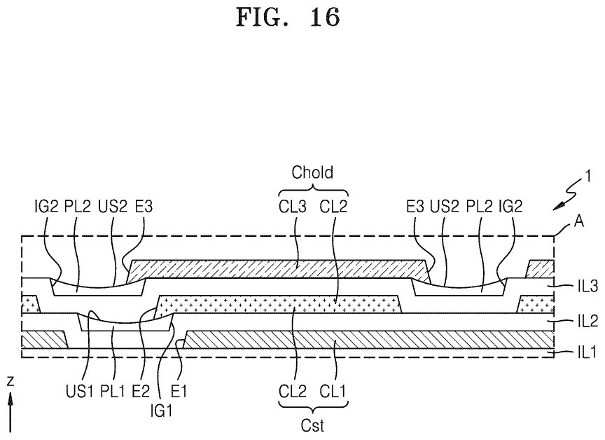

Referring to FIGS. 6 and 16, the method 2 of manufacturing a display device may include disposing a third conductive layer CL3 on the third inorganic layer IL3 and the second planarization layer PL2 (S14).

In the disposing of the third conductive layer CL3 (S14), the third conductive layer CL3 may be disposed to overlap the second conductive layer CL2. In addition, an end E3 of the third conductive layer CL3 may be in contact with the second planarization layer PL2. The second conductive layer CL2 and the third conductive layer CL3, which overlap each other in a plan view, may be disposed with the third inorganic layer IL3 therebetween. The second conductive layer CL2 and the third conductive layer CL3 may constitute a second capacitor Chold, and the third inorganic layer IL3 may act as a dielectric layer.

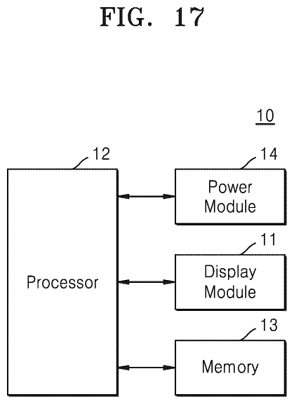

FIG. 17 is a block diagram of an electronic device 10 according to an embodiment.

Referring to FIG. 17, the electronic device 10 according to an embodiment may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

Data information necessary for the operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information on a display screen.

The power module 14 may include a power supply module, such as a power adapter or a battery device, and a power conversion module configured to convert power supplied by the power supply module to generate power necessary for the operation of the electronic device 10.

At least one of the components of the electronic device 10 may be included in the display device according to the embodiments described above. Furthermore, some of the individual modules functionally included in a single module may be included in the display device, and others may be provided separately from the display device. For example, the display device may include the display module 11, and the processor 12, the memory 13, and the power module 14 may be provided in the form of other devices within the electronic device 10 other than the display device.

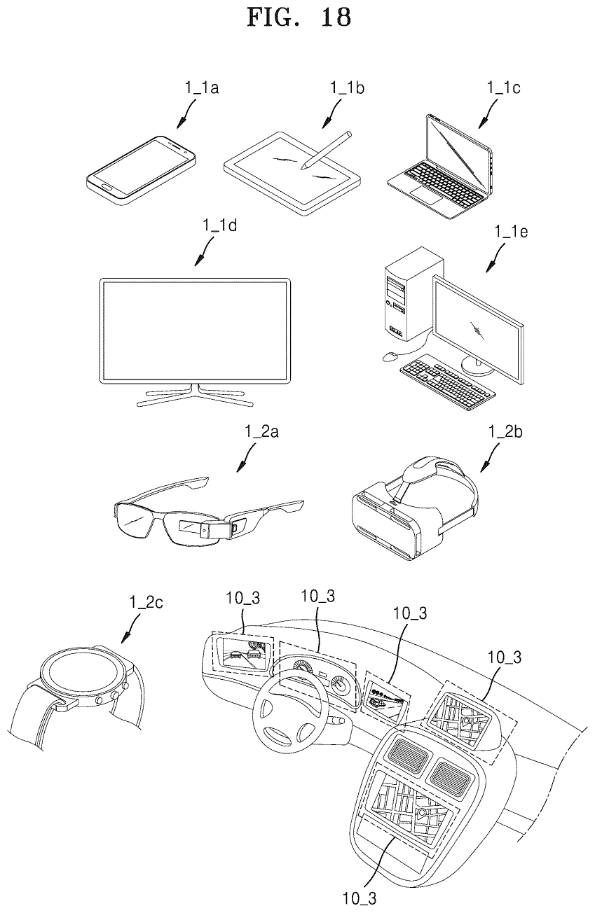

FIG. 18 shows schematic diagrams of electronic devices according to various embodiments.

Referring to FIG. 18, various electronic devices, to which the display devices according to embodiments are applied, may include electronic devices for mage display, such as a smartphone 10_1a, a tablet personal computer (PC) 10_1b, a laptop 10_1c, a television (TV) 10_1d, or a desk monitor 10_1e, wearable electronic devices each including a display module, such as smart glasses 10_2a, a head mounted display 10_2b, or a smart watch 10_2c, and vehicle electronic devices 10_3 each including a display module, such as dashboards of automobiles, center information displays (CIDs) on the center fascia or dashboards of automobiles, or room mirror displays.

According to embodiments, capacitor space efficiency and durability may be effectively improved, and the quality of the display device may be effectively improved.

The effects of the disclosure are not limited to those described above, and other effects that are not described herein will be clearly understood from the description of the claims by those of ordinary skill in the art.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a first inorganic layer disposed on the substrate;
a first conductive layer disposed on the first inorganic layer;
a second inorganic layer disposed on the first inorganic layer and covering the first conductive layer, wherein the second inorganic layer defines a first groove portion in an upper portion thereof;
a first planarization layer accommodated in the first groove portion; and
a second conductive layer disposed on the second inorganic layer and the first planarization layer.

2. The display device of claim 1, wherein an end of the second conductive layer is in contact with the first planarization layer.

3. The display device of claim 1, wherein an etch selectivity of the first planarization layer with respect to the second inorganic layer is greater than 1.

4. The display device of claim 1, wherein an upper surface of the first planarization layer is concave.

5. The display device of claim 1, further comprising:
a third inorganic layer disposed on the second inorganic layer and the first planarization layer and covering the second conductive layer, wherein the third inorganic layer defines in an upper portion thereof a second groove portion overlapping the first groove portion in a plan view;
a second planarization layer accommodated in the second groove portion;
a third conductive layer disposed on the third inorganic layer and the second planarization layer; and
a fourth inorganic layer disposed on the third inorganic layer and the second planarization layer and covering the third conductive layer.

6. The display device of claim 5, wherein the first conductive layer, the second conductive layer, and the third conductive layer overlap each other in the plan view.

7. The display device of claim 5, wherein an end of the third conductive layer is in contact with the second planarization layer.

8. The display device of claim 5, wherein the second inorganic layer and the third inorganic layer comprise a same material, and
the first planarization layer and the second planarization layer comprise a same material.

9. The display device of claim 5, wherein an upper surface of the second planarization layer is concave.

10. An electronic device comprising:
a substrate;
a first inorganic layer disposed on the substrate;
a first conductive layer disposed on the first inorganic layer;
a second inorganic layer disposed on the first inorganic layer and covering the first conductive layer, wherein the second inorganic layer defines in an upper portion thereof a first groove portion;
a first planarization layer accommodated in the first groove portion; and
a second conductive layer disposed on the second inorganic layer and the first planarization layer,
wherein an end of the second conductive layer is in contact with the first planarization layer, and
an etch selectivity of the first planarization layer with respect to the second inorganic layer is greater than 1.

11. A method of manufacturing a display device, the method comprising:
disposing a first inorganic layer on a substrate;
disposing a first conductive layer on the first inorganic layer;
disposing a second inorganic layer on the first inorganic layer to cover the first conductive layer, wherein the second inorganic layer defines in an upper portion thereof a first groove portion;
disposing a first planarization layer on the second inorganic layer, wherein the first planarization layer defines in an upper portion thereof a first planarization groove portion overlapping the first groove portion in a plan view;
disposing a first sacrificial layer on the first planarization layer such that at least a portion of the first sacrificial layer is accommodated in the first planarization groove portion;
removing a portion of the first sacrificial layer to expose an upper surface of the first planarization layer;
removing a portion of the first planarization layer and a remainder of the first sacrificial layer such that an upper surface of the second inorganic layer is exposed; and
disposing a second conductive layer on the second inorganic layer and the first planarization layer.

12. The method of claim 11, wherein, after disposing the first sacrificial layer, an upper surface of the first sacrificial layer becomes flat.

13. The method of claim 11, wherein, after removing the portion of the first sacrificial layer, an upper surface of the first sacrificial layer and the upper surface of the first planarization layer become on a same plane.

14. The method of claim 11, wherein, after removing the portion of the first planarization layer and the remainder of the first sacrificial layer, the upper surface of the first planarization layer becomes concave.

15. The method of claim 11, wherein, after disposing the second conductive layer, an end of the second conductive layer becomes in contact with the first planarization layer.

16. The method of claim 11, wherein an etch selectivity of the first planarization layer with respect to the second inorganic layer is greater than 1.

17. The method of claim 11, further comprising:
disposing a third inorganic layer on the second inorganic layer and the first planarization layer to cover the second conductive layer, wherein the third inorganic layer defines in an upper portion thereof a second groove portion overlapping the first groove portion in the plan view;
disposing a second planarization layer on the third inorganic layer, wherein the second planarization layer defines in an upper portion thereof a second planarization groove portion overlapping the second groove portion in the plan view;
disposing a second sacrificial layer on the second planarization layer such that at least a portion of the second sacrificial layer is accommodated in the second planarization groove portion;
removing a portion of the second sacrificial layer to expose an upper surface of the second planarization layer;
removing a portion of the second planarization layer and a remainder of the second sacrificial layer such that an upper surface of the third inorganic layer is exposed; and
disposing a third conductive layer on the third inorganic layer and the second planarization layer.

18. The method of claim 17, wherein the first conductive layer, the second conductive layer, and the third conductive layer overlap each other in the plan view.

19. The method of claim 17, wherein the second inorganic layer and the third inorganic layer comprise a same material, and
the first planarization layer and the second planarization layer comprise a same material.

20. The method of claim 17, wherein, after removing the portion of the second planarization layer and the remainder of the second sacrificial layer, the upper surface of the second planarization layer becomes concave.
